(19) United States
(12) Patent Application Publication
(10) Pub. No.: US 2017/0062311 A1
(43) Pub. Date: Mar. 2, 2017

(54) INTEGRATED CIRCUIT WITH ON-DIE POWER DISTRIBUTION BARS

(71) Applicant: FREESCALE SEMICONDUCTOR, INC., Austin, TX (US)

(72) Inventors: Chee Seng Foong, Austin, TX (US); Yin Kheng Au, Petaling Jaya (MY); Ly Hoon Khoo, Klang (MY); Wen Shi Koh, Petaling Jaya (MY); Pei Fan Tong, Bukit Jalil (MY)

(21) Appl. No.: 14/833,149

(22) Filed: Aug. 24, 2015

(51) Int. Cl. H01L 23/495; H01L 21/56; H01L 23/31; H01L 21/48; H01L 21/683; H01L 23/00; H01L 21/78

(52) U.S. Cl. CPC H01L 23/49541; H01L 24/85; H01L 21/565; H01L 21/561; H01L 21/78; H01L 23/49503; H01L 21/4821; H01L 21/6835; H01L 23/3107; H01L 24/49; H01L 2224/48247; H01L 2924/14

(57) ABSTRACT

A packaged IC device has a power bar assembly with one or more power distribution bars, mounted on top of the IC die, which enables assembly using a lead frame that does not include any power distribution bars. External power supply voltages are brought to the IC die by (i) a corresponding first bond wire that connects a lead frame lead to a corresponding die-mounted power distribution bar and (ii) a corresponding second bond wire that connects the power distribution bar to a corresponding bond pad on the IC die. As such, different types of packaged IC devices having different numbers and/or configurations of power distribution bars can be assembled using a single, generic lead frame design having a die pad, tie bars, and leads, but no power distribution bars.

### BACKGROUND

The present invention relates to packaged integrated circuit (IC) devices and, more particularly, to packaged IC dies having power distribution bars.

Many packaged IC devices are assembled using lead frames having power distribution bars that provide multiple different power supply voltages for the IC die located within the device package. It is common for different types of packaged IC devices to require different numbers of power supply voltages in different configurations around the IC dies. As such, conventional assembly techniques for such different types of packaged IC devices require a unique lead frame design for each different type of packaged IC device.

FIG. 1 is a top plan view of a first conventional frame 100 for a first type of packaged IC device. As shown in FIG. 1, the lead frame 100 has a die pad 102 surrounded by four power distribution bars 104, four tie bars 106, and 176 leads 108. Note that the tie bars 106 are connected to a support ring 110 that is physically and electrically connected to the die pad 102. In many packaged IC devices, the die pad 102, the tie bars 106, and the support ring 110 are grounded, and one or more bond pads of the IC die are wire-bonded to one or more of those structures to provide a ground voltage to the IC die.

FIGS. 2A and 2B are, respectively, a top plan view and partial cross-sectional side view of a partially assembled packaged IC device 200 assembled using the lead frame 100 of FIG. 1. As shown in FIGS. 2A and 2B, an IC die 212 is mounted onto the die pad 102 and wire-bonded using bond wires 214 to the power distribution bars 104, the support ring 110, and the leads 108.

As used in this specification, a conventional power bar, such as the power bars 104 of FIG. 1, is a strip of conductive material (e.g., metal) that runs substantially parallel to one of the sides of the rectangular die pad 102 as compared to the tie bars 106 and the leads 108, which extend substantially radially from the die pad 102. Typically, each lead 108 is connected to at most one die bond pad (not explicitly shown) on the IC die 212 with a bond wire, while each power bar 104 may be wire-bonded (i.e., connected with one or more bond wires) to multiple different die bond pads to provide that same power supply voltage to different locations of the IC die 212.

FIG. 3 is a top plan view of another conventional lead frame 300 for a second type of packaged IC device. As shown in FIG. 3, the lead frame 300 has a die pad 302 surrounded by seven power distribution bars 304, four tie bars 306, 176 leads 308, and a support ring 310.

The lead frame 100 of FIG. 1 cannot be used to assemble the second type of packaged IC devices if they require more than four different power supply voltages, and, while the lead frame 300 of FIG. 3 can in theory be used to assemble the first type of packaged IC devices, it can be inefficient to do so, with one or more of the existing power distribution bars 304 not being used. Moreover, the lead frame 300 cannot be used to assembly other types of packaged IC devices that require more than seven different power supply voltages.

### BRIEF DESCRIPTION OF THE DRAWINGS

Embodiments of the invention will become more fully apparent from the following detailed description, the appended claims, and the accompanying drawings in which like reference numerals identify similar or identical elements.

FIG. 1 is a top plan view of a first conventional lead frame for a first type of packaged IC device;

FIGS. 2A and 2B are, respectively, a top plan view and partial cross-sectional side view of a partially assembled packaged IC device assembled using the lead frame of FIG. 1;

FIG. 3 is a top plan view of a second conventional lead frame for a second type of packaged IC device;

FIG. 4 is a top plan view of a generic lead frame that can be used to assemble different types of packaged IC devices in accordance with the present invention;

FIGS. 5A and 5B are a top plan view and a side view, respectively of a power bar assembly of the invention for a first type of packaged IC device;

FIG. 6 is a side view of the power bar assembly of FIGS. 5A and 5B mounted on an IC die;

FIG. 7 is a partial cross-sectional side view of a partially assembled packaged IC device assembled using the generic lead frame of FIG. 4, the power bar assembly of FIGS. 5A and 5B, and the IC die of FIG. 6;

FIGS. 8A-8F are cross-sectional side views of different stages in the assembly of multiple instances of the power bar assembly of FIGS. 5A and 5B arranged in a linear or two-dimensional array; and

FIGS. 9A-9D are side views and FIGS. 9E-9F are cross-sectional side views of different stages in the assembly of multiple instances of packaged IC devices according to one embodiment of the invention.

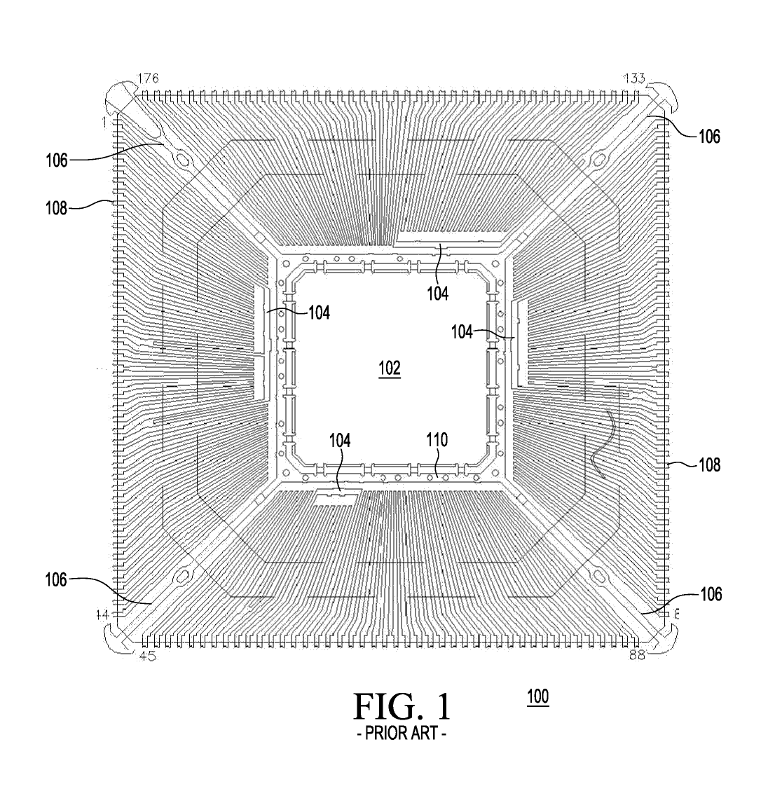

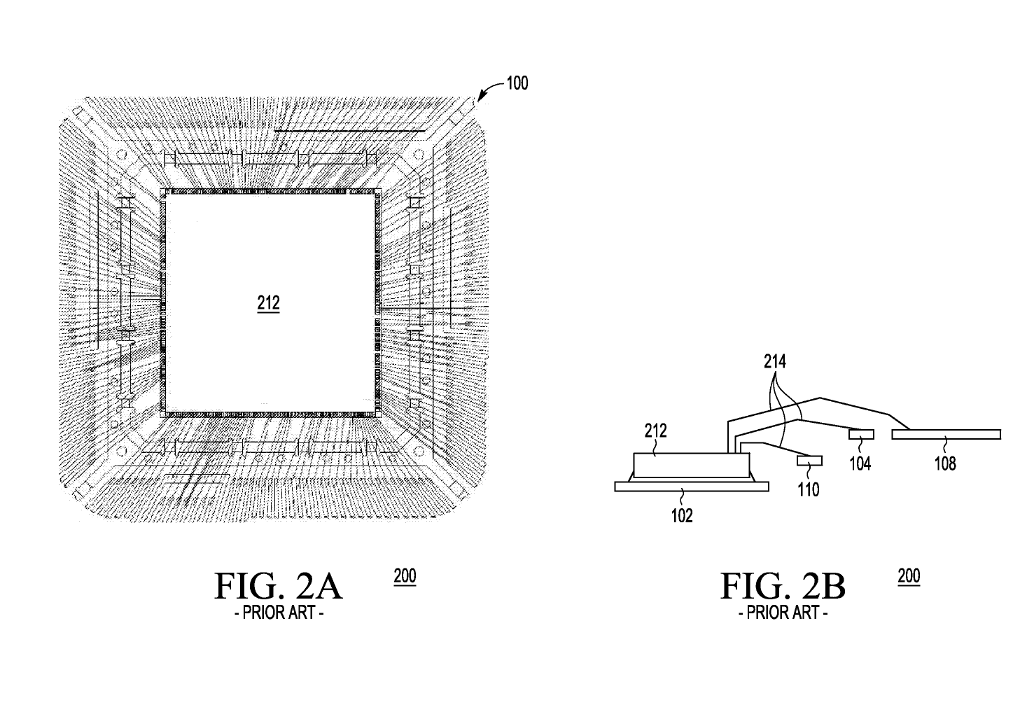

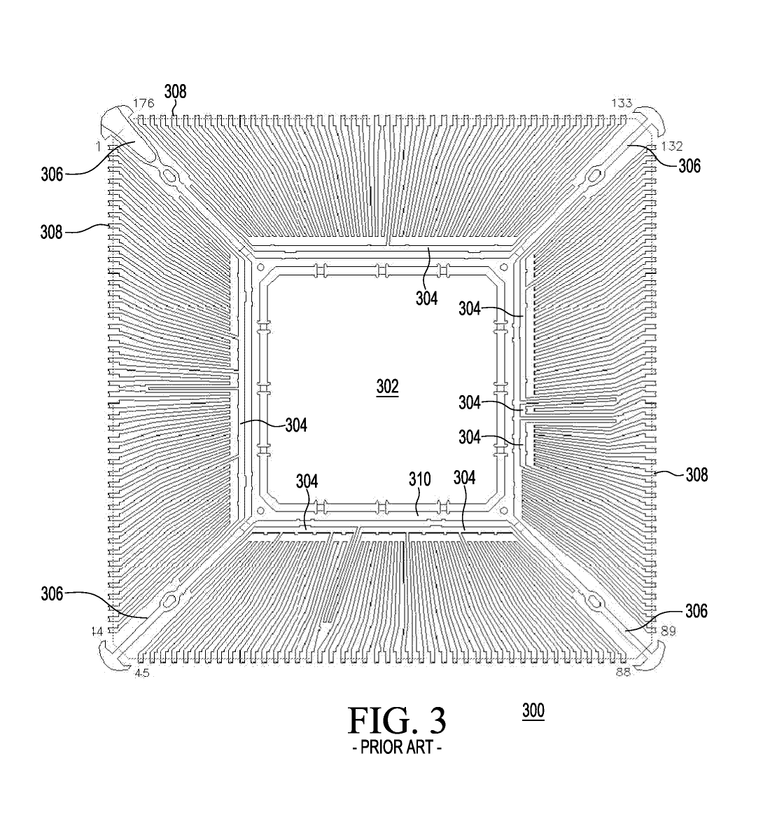

### DETAILED DESCRIPTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

One embodiment is a method for assembling a packaged integrated circuit (IC) device. The method comprises (a) mounting an IC die onto a die pad of a lead frame; (b) mounting, onto the IC die, a power bar assembly comprising one or more electrically isolated power distribution bars on a top surface of a non-conductive substrate; (c) using bond wires, wire bonding (i) one or more of the power distribution bars of the power bar assembly to one or more bond pads on the IC die and to one or more leads of the lead frame and (ii) one or more bond pads on the IC die to one or more leads of the lead frame; and (d) applying molding compound to encapsulate the one or more power distribution bars, the IC die, the bond wires, and portions of the leads.

Another embodiment is a packaged IC device assembled using the method of the previous paragraph.

Yet another embodiment is a packaged IC device comprising (1) a lead frame comprising a die pad surrounded by a plurality of leads; (2) an IC die mounted onto the die pad; (3) a pre-assembled power bar assembly mounted onto the IC die, the power bar assembly comprising one or more electrically isolated power distribution bars on a top surface of a non-conductive substrate; (4) a plurality of bond wires electrically connecting (i) one or more of the power distribution bars of the power bar assembly to one or more bond pads on the IC die and to one or more leads of the lead frame and (ii) one or more bond pads on the IC die to one or more leads of the lead frame; and (5) molding compound encapsulating the one or more power distribution bars, the IC die, the bond wires, and portions of the leads.

According to certain embodiments of the invention, two or more different types of packaged IC devices are assembled (i) with their power distribution bars mounted on top of their IC dies and (ii) using lead frames that do not have any power distribution bars. As such, these different types of packaged IC devices, potentially having different numbers and/or configurations of power distribution bars mounted on their IC dies, can all be assembled using the same, generic lead frame design.

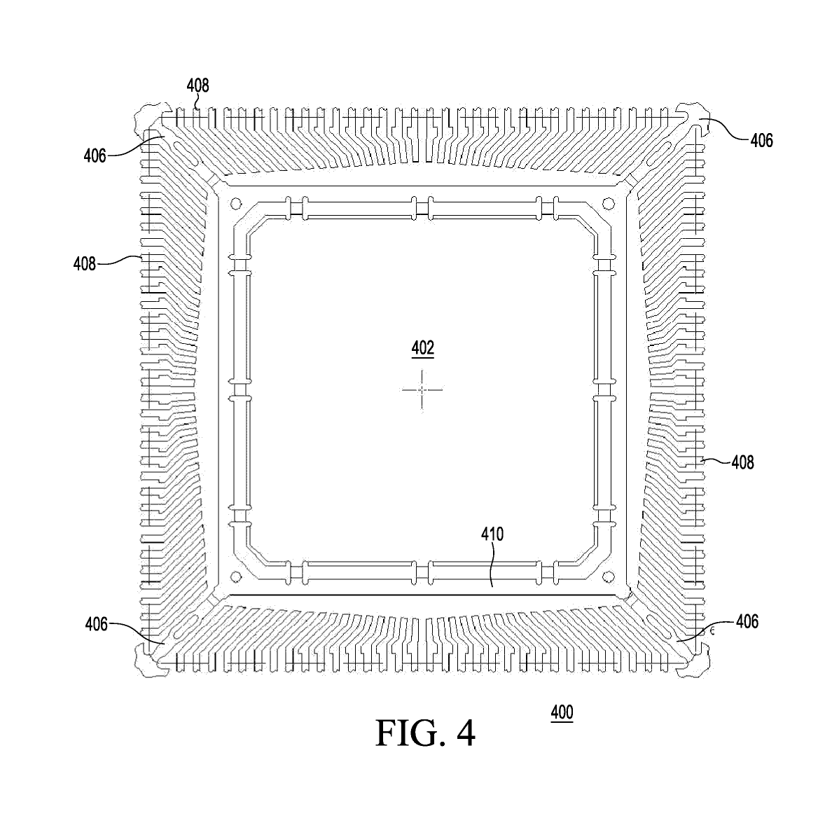

FIG. 4 is a top plan view of a generic lead frame 400 that can be used to assemble different types of packaged IC devices of the invention. As shown in FIG. 4, the lead frame 400 has a die pad 402 surrounded by four tie bars 406, 128 leads 408, and a support ring 410, but no power distribution bars.

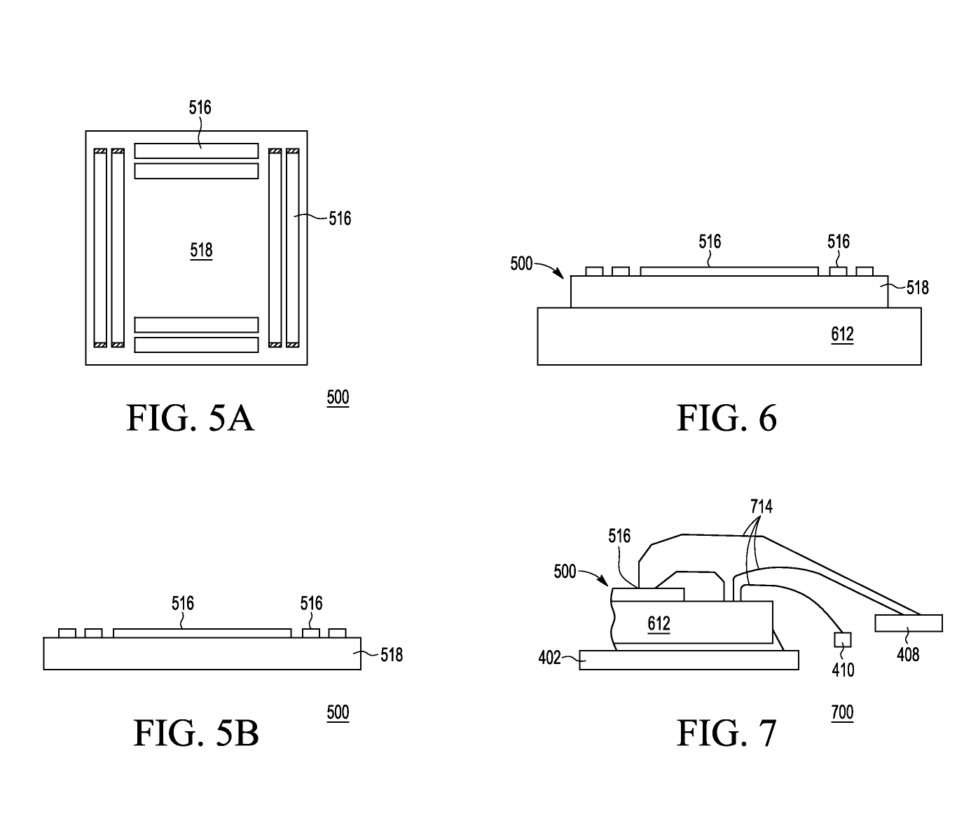

FIGS. 5A and 5B are a top plan view and a side view, respectively of a power bar assembly 500 of the invention for a first type of packaged IC device. As shown in FIGS. 5A and 5B, the power bar assembly 500 comprises eight different, electrically isolated, conductive (e.g., metal) strips 516 mounted onto a non-conductive (e.g., plastic) substrate 518.

FIG. 6 is a side view of the power bar assembly 500 of FIGS. 5A and 5B mounted onto an IC die 612.

FIG. 7 is a partial cross-sectional side view of a partially assembled packaged IC device 700 assembled using the generic lead frame 400 of FIG. 4, the power bar assembly 500 of FIGS. 5A and 5B, and the IC die 612 of FIG. 6. As shown in FIG. 7, the power bar assembly 500 is mounted onto the IC die 612, which is itself mounted onto the die pad 402 of the lead frame 400. In addition, different bond pads (not explicitly shown) on the top surface of the IC die 612 are wire-bonded using bond wires 714 to the power bars 516 of the power bar assembly 500, to the (e.g., grounded) support ring 410 of the lead frame 400, and to the leads 408. In addition, the same power bar 516 is wire-bonded to another bond pad (not explicitly shown) of the IC die 612. In this way, a particular power supply voltage can be provided to a particular die bond pad on the IC die 612 from a suitable external power supply (not shown) via a particular lead 408, which is connected using a corresponding bond wire 714 to the power bar 516, which is in turn connected to the die bond pad using another bond wire 714. Note that, depending on the current loads that need to be supported, multiple leads 408 and multiple bond wires 714 may be used in parallel to bring a particular power supply voltage to the IC die via multiple die bond pads.

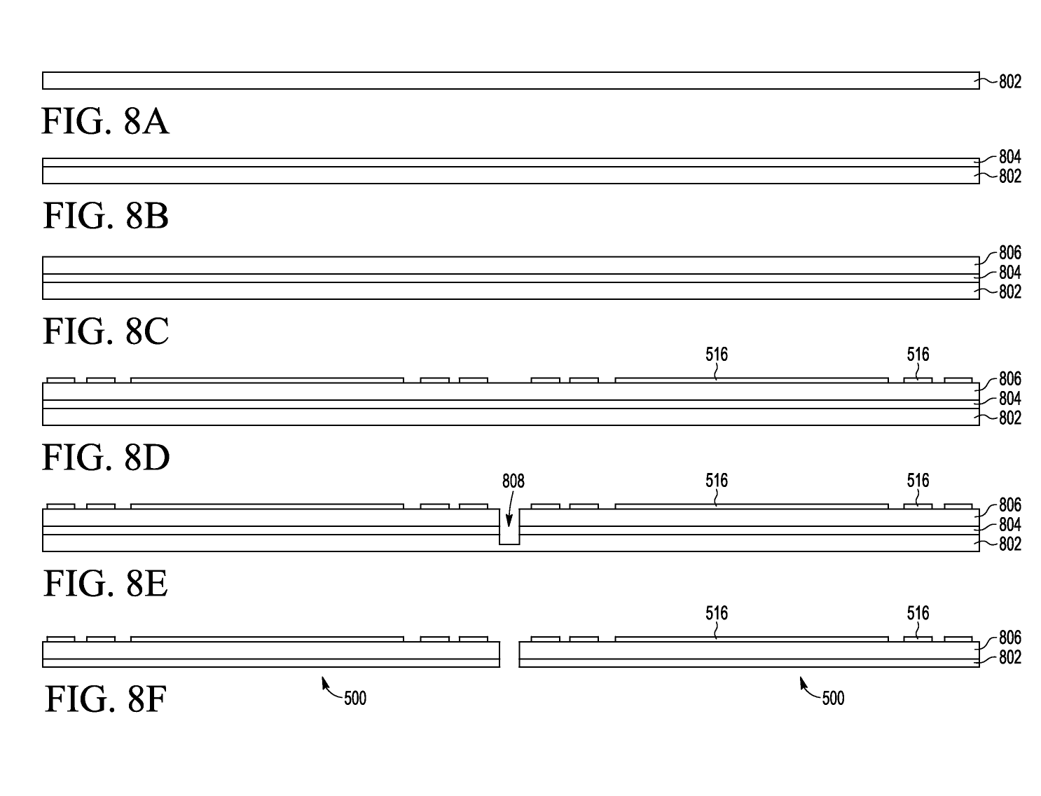

FIGS. 8A-8F are cross-sectional side views of different stages in the assembly of multiple instances of the power bar assembly 500 of FIGS. 5A and 5B arranged in a linear or two-dimensional array. In particular, FIG. 8A shows temporary support substrate 802, made, for example, of a suitable plastic like Mylar film from Dupont TeIjin Films of Chester, Virginia. FIG. 8B shows a sheet of adhesive die attach film (DAF) tape 804 applied to the top surface of the temporary support substrate 802. FIG. 8C shows a sheet of non-conductive substrate material 806, such as a suitable flexible plastic tape, applied to the top surface of the sheet of DAF tape 804.

FIG. 8D shows the sub-assembly after strips of conductive material (e.g., metal) constituting the power bars 516 have been formed on the top surface of the sheet of non-conductive substrate material 806. The power bars 516 may be formed using any suitable technique such as by metal plating or screen printing. FIG. 8E shows the sub-assembly after being sawed completely through the sheet of non-conductive substrate material 806 and the sheet of DAF tape 804, but only partially through the temporary support substrate 802. FIG. 8E shows one of the saw kerfs 808 resulting from such sawing. FIG. 8F shows two separated instances of the power bar assembly 500 after the assemblies are removed from the of temporary support substrate 802.

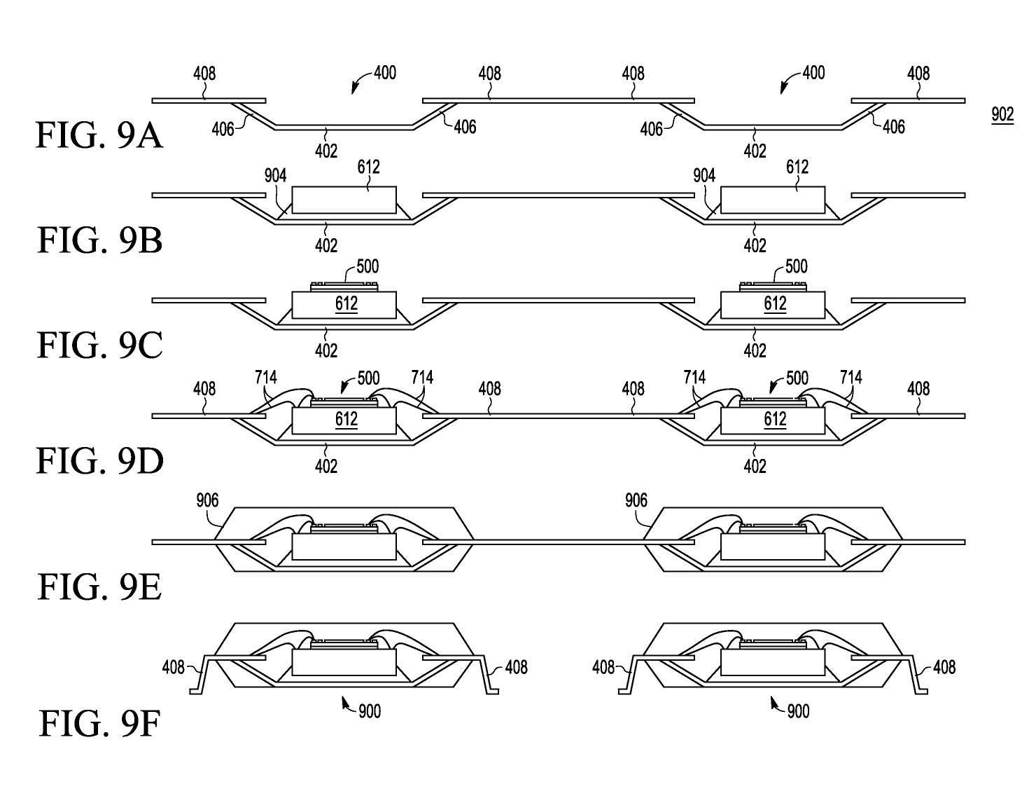

FIGS. 9A-9D are side views and FIGS. 9E-9F are X-ray side views of different stages in the assembly of multiple instances of packaged IC devices 900 according to one embodiment of the invention. In particular, FIG. 9A shows a portion of a one- or two-dimensional lead frame array 902 comprising a plurality of instances of the lead frame 400 of FIG. 4, two of which are represented in FIG. 9A. FIG. 9B shows the resulting sub-assembly after an IC die 612 has been picked, placed, and mounted onto the die pad 402 of each lead frame 400 using a suitable epoxy 904. FIG. 9C shows the resulting sub-assembly after instances of the power bar assembly 500 of FIGS. 5A and 5B have been picked, placed, and mounted on top of the IC dies 612. Note that the power bar assembly 500 is sized and placed so as to avoid interfering with the die bond pads on the top surface of the corresponding IC die 612.

FIG. 9D shows the resulting sub-assembly after bond wires 714 have been wire-bonded (i) to connect the IC dies 612 to (a) the power bars 516 of the power bar assemblies 500 and to (b) the leads 408 of the lead frames 400 and (ii) to connect the power bars 516 to the leads 408. FIG. 9E shows the resulting sub-assembly after encapsulation with a suitable molding compound 906. FIG. 9F shows two packaged IC devices 900 that result from singulating the sub-assembly of FIG. 9E and trimming a forming the leads 408 into gull-wing shapes.

Each packaged IC device 900 is assembled using an instance of the lead frame 400 of FIG. 4 and an instance of the power bar assembly 500 of FIGS. 5A and 5B having eight electrically isolated power bars 516. As such, each package IC device 900 can, in theory, support up to eight different, externally applied power supply voltages. According to the invention, different instances of the same lead frame 400 can be used to assemble a wide variety of different types of package IC devices using different power bar assemblies having a different number and/or configuration of power bars. In this way, the lead frame 400 functions as a generic or universal lead frame for use in the assembly of those different types of packaged IC devices.

Although the invention has been described in the context of the particular embodiment shown in the figures, the invention is not so limited. For example:

Other power bar assemblies of the invention may assembled using techniques other than that shown in FIGS. 8A-8F;

Other packaged IC devices of the invention may be assembled using techniques other than that shown in FIGS. 8A-8F;

Other packaged IC devices of the invention may have two or more IC dies mounted side by side and/or stacked on top of one another with one or more of those IC dies having power bar assemblies mounted thereon; and

Other packaged IC devices of the invention may be assembled using lead frames that have no ground structures to be wire-bonded to the IC die. In such embodiments, one or more of the power distribution bars mounted on top of the IC die may be used to provide a ground voltage to the IC die.

A lead frame is a collection of metal leads and possibly other elements (e.g., power bars, die paddles also known as die pads and die flags) that is used in semiconductor packaging for assembling one or more integrated circuit (IC) dies into a single packaged semiconductor device. Prior to assembly into a packaged device, a lead frame may have support structures (e.g., a rectangular metal frame and tie bars) that keep those elements in place. During the assembly process, the support structures may be removed. As used herein, the term “lead frame” may be used to refer to the collection of elements before assembly or after assembly, regardless of the presence or absence of those support structures.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain embodiments of this invention may be made by those skilled in the art without departing from embodiments of the invention encompassed by the following claims.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

1-12. (canceled)

13. A packaged integrated circuit (IC) device, comprising:
a lead frame comprising a die pad surrounded by a plurality of leads;
an IC die mounted on the die pad;
a pre-assembled power bar assembly mounted on the IC die, wherein the power bar assembly is located entirely within a footprint of the IC die, the power bar assembly comprising one or more electrically isolated power distribution bars on a top surface of a non-conductive substrate, wherein the plurality of leads are horizontally spaced from the pre-assembled power bar assembly;
a plurality of bond wires electrically connecting (i) one or more of the power distribution bars of the power bar assembly to the IC die and to one or more leads of the lead frame and (ii) the IC die to one or more leads of the lead frame; and
molding compound encapsulating the one or more power distribution bars, the IC die, the bond wires, and portions of the leads.

14. The packaged IC device of claim 13, wherein the power bar assembly comprises:
an adhesive material;
the non-conductive substrate mounted on the adhesive material; and
the one or more power distribution bars mounted on the top surface of the non-conductive substrate.

15. The packaged IC device of claim 14, wherein:
the adhesive material is an adhesive tape; and
the non-conductive substrate is flexible tape.

16. The packaged IC device of claim 14, wherein the power distribution bars are electroplated on the top surface of the non-conductive substrate.

17. The packaged IC device of claim 13, wherein the pre-assembled power bar assembly comprises more than one electrically isolated power distribution bar located along a perimeter of the non-conductive substrate.
